(19) United States
(12) Patent Application Publication
(10) Pub. No.: US 2020/0088776 A1
(43) Pub. Date: Mar. 19, 2020

(54) METHOD FOR DETECTING A FAULT STATE, CONTROL DEVICE, BATTERY SENSOR AND VEHICLE ON-BOARD NETWORK

(71) Applicant: Continental Automotive GmbH, Hannover (DE)

(72) Inventor: HANS-MICHAEL GRAF, Regensburg (DE)

(21) Appl. No.: 16/067,878

(22) PCT Filed: Feb. 20, 2017
(86) PCT No.: PCT/EP2017/053777

§ 371 Date: Jul. 3, 2018

(30) Foreign Application Priority Data
Mar. 24, 2016 (DE) 102016204946.1

(51) Int. Cl. G01R 31/00; G01R 31/3835; G01R 31/02

(52) U.S. Cl. CPC G01R 31/006; G01R 31/025; G01R 31/3835

(57) ABSTRACT

A method for detecting a fault state in a vehicle electrical system by monitoring a line voltage of a connection line. Also disclosed are an associated control apparatus, an associated battery sensor and an associated vehicle electrical system.

### CROSS REFERENCE TO RELATED APPLICATIONS

This application is the U.S. National Phase Application of PCT/EP2017/053777, filed Feb. 20, 2017, which claims priority to German Patent Application No. 10 2016 204 946.1, filed Mar. 24, 2016, the contents of such applications being incorporated by reference herein.

### FIELD OF THE INVENTION

The invention relates to a method for detecting a fault state in a vehicle electrical system by means of a battery sensor and a control apparatus. The invention further relates to an associated control apparatus, an associated battery sensor and an associated vehicle electrical system.

In motor vehicles having a conventional vehicle electrical system, only one battery is typically available and supplies all loads, including the starter, with energy if a generator no longer provides any energy. However, two redundant electrical energy sources, namely a battery and a generator, are available in the case of a running internal combustion engine since the generator is driven by the internal combustion engine. If one of the energy sources fails, the respective other source can continue to supply the vehicle electrical system. The battery may be, in particular, a typical automobile battery, that is to say a rechargeable battery.

For reasons of minimizing consumption, motor vehicles have recently been equipped with automatic stop-start systems. These can switch off the internal combustion engine at very low speeds of the motor vehicle or, in particular, also at a standstill. This dispenses with the generator as a second, redundant power source. Should the battery fail at the same time, a protected restart of the internal combustion engine would not be possible. Such a failure can endanger the safety of the vehicle occupants, in particular, when stopped on railroad tracks, for example.

In order to minimize the risk of a battery failure, motor vehicles with stop-start systems are usually equipped with battery sensors, in particular intelligent battery sensors, which make it possible to monitor the battery and hence the ability of the motor vehicle to start. Should a weak battery be identified, the internal combustion engine is typically not deactivated.

However, in addition to the failure of the battery as a power source, the connection between the battery and the vehicle electrical system can also be lost. This connection is usually in the form of a cable connection. On the negative side, a cable typically leads to the body as ground. On the positive side, a cable typically leads to a distribution box. In the case of a battery sensor, the current is additionally guided through a measuring resistor, also referred to as a shunt resistor. This additional component increases the risk of the electrical connection between the battery and the vehicle electrical system being interrupted.

### BACKGROUND OF THE INVENTION

Therefore, an aspect of the invention is to provide a method which makes it possible, for example, to detect an interruption in the current path inside a battery sensor, while a generator is providing power. In this case, the focus is on a battery sensor which is installed on the negative side of a battery and is connected to a control device or a control apparatus via a connection line, sometimes also referred to as LIN. In particular, the intention is to detect a breakage of a measuring cable. An aspect of the invention is also to provide a control apparatus and a battery sensor each for carrying out the method according to an aspect of the invention and to provide a vehicle electrical system having such a control apparatus or such a battery sensor.

Advantageous configurations can be gathered, for example, from the respective claims. The content of the claims is incorporated in the content of the description by express reference.

An aspect of the invention relates to a method for detecting a fault state in a vehicle electrical system by means of a battery sensor and a control apparatus. The battery sensor and the control apparatus are connected to one another via at least one connection line for the purpose of communication. One connection line or else two or more connection lines may therefore be present, for example. These may be in the form of an LIN connection, for example.

The method has the following steps:
measuring a line voltage on the connection line,
determining whether the line voltage is within at least a predefined normal range, and
determining the fault state if the line voltage is outside the normal range.

The method according to an aspect of the invention is based on the knowledge that, in the case of a normal function, voltages on the connection line are typically within a normal range which can be well delimited and predicted, but are outside this normal range in the event of particular malfunctions. This will be discussed in more detail further below. It should be understood that the method according to an aspect of the invention can be implemented, in particular, by carrying out a more accurate measurement of voltage values on the connection line, which normally transmits only digital signals and it therefore suffices to be able to distinguish the presence of a logic “0” from a logic “1”, that is to say by not only distinguishing two states, but rather measuring the voltage values continuously or quasi-continuously at least within a certain voltage range. In other words, a value of the line voltage can therefore be stated in volts instead of only being able to state the digital state. This is typically understood by the term “measuring a line voltage” within the scope of this application. However, it is also possible to determine, for example, whether the voltage is inside or outside the normal range or is in another range. This also constitutes a modification of the functionality which distinguishes only the logic levels.

The fault state can correspond, in particular, to a loss of a connection between the battery sensor and ground. The ground can be, in particular, a vehicle ground which is formed by a chassis of the vehicle, for example.

The method can be carried out in the control apparatus, but can also be carried out in the battery sensor.

The normal range is typically in a positive voltage range. This means, in particular, that both the lower limit and the upper limit of the normal range are positive voltage values.

One embodiment may also provide for the fault state to be determined only when the line voltage is in a fault range. This fault range is preferably in the negative voltage range. This means, in particular, that both the lower limit and the upper limit of the fault range are negative voltage values.

This procedure is based on the knowledge that voltage values of the line voltage are typically in a particular fault range which is permanently and easily predictable. This can be used as additional control in order to avoid detecting such a fault state on account of another malfunction. However, the use of the fault range can also be considered to be an alternative to the use of the normal range, that is to say a fault state is already detected when the line voltage is in the fault range. In this case, the method can be fundamentally carried out in such a manner that a fault state is detected when the line voltage is outside the normal range or inside the fault range, or a fault state can also only be detected when the line voltage is in the fault range without the normal range actually being checked.

The line voltage is preferably measured relative to a reference potential which is preferably generated by means of a pull-up resistor in the form of a voltage divider. This allows the use of particular voltage measuring devices, as will be explained in more detail further below.

The fault state can also be determined on the basis of one or more of the following criteria:
AC voltage component of a battery voltage measured by the battery sensor, wherein a fault state can be determined, in particular, when this AC voltage component is above a corresponding threshold value,
current measured by the battery sensor, in particular battery current, which is below a threshold value in terms of absolute value and therefore indicates the presence of an interruption in the line,
comparison of the battery voltage measured by the battery sensor with a normal value or with a further normal range, wherein a deviation of the battery voltage from the normal value or normal range can likewise indicate an interrupted line.

These criteria can be used both individually and in any desired combination. They can also be used to safeguard the procedure already described further above, but alternatively can also be used separately, for example, in order to determine a fault state.

A fault state can be determined even if the communication between the battery sensor and the control apparatus is terminated. Such termination may be based, for example, on the fact that the battery sensor is no longer supplied with electrical power, which likewise indicates a corresponding malfunction.

According to one embodiment, the line voltage is measured at the battery sensor, wherein the line voltage and a battery voltage are measured using multiplexing. This makes it possible to use a single voltage measuring device, for example a voltmeter, to measure both the battery voltage and the line voltage. The battery voltage is typically that variable which is intended to be normally measured by the battery sensor in order to monitor the battery.

The line voltage can be measured, in particular, while the connection line is connected to ground opposite the voltage-measuring unit and is not connected to ground at the voltage-measuring unit. If the line voltage is therefore measured at the battery sensor, for example, the connection line is typically not connected to ground at the battery sensor, whereas it is connected to ground at the control apparatus, that is to say opposite. This allows the respective ground of the opposite unit to be measured, which can be advantageously used to detect the fault state. This will be discussed in more detail further below.

The same also naturally applies the other way round, with the result that, if the line voltage is measured at the control apparatus, the connection line is not connected to ground at the control apparatus, whereas it is connected to ground at the battery sensor.

The line voltage can be measured, in particular, with a low level over a plurality of data transmission cycles. In a similar manner to the embodiment already described, this allows measurement while the connection line is pulled to ground by the respective other unit. If a plurality of cycles are used, averaging or a more reliable measurement can be achieved. A sample-and-hold circuit can also be used for this purpose, for example.

The fault state can correspond, for example, to a loss of a connection between the battery sensor and the battery. For this case, the line voltage can be measured, in particular, with a high level over a number or a plurality of data transmission cycles. This allows a loss of a connection between the battery sensor and the battery to be determined, in which case it should be pointed out that a fault state in the form of a loss of a connection between the battery sensor and ground, in particular, was discussed further above. It should be understood that the method can be carried out in such a manner that only one of the two fault states described is detected or can also be carried out in such a manner that both fault states described or possibly also further fault states can be detected and possibly also distinguished from one another.

It should be understood that the battery sensor is typically supplied from the battery or from the vehicle electrical system. Otherwise, the battery sensor will typically fail if it does not have another power supply. As already mentioned, such a failure may be detected, for example, as termination of the communication between the battery sensor and the control apparatus and can also indicate a fault state, in particular.

According to one preferred embodiment, the disconnection of an internal combustion engine is deactivated in response to the determination of the fault state. This makes it possible to prevent, in the event of a fault in the electrical system of a vehicle, the second power source, namely the generator typically driven by the internal combustion engine, from also being deactivated and therefore the threat of the vehicle breaking down, which would expose the vehicle and its occupants and other road users to a considerable danger.

However, other measures for achieving a safe vehicle state are also conceivable. For example, an additional battery or other power source may be connected or a braking or stopping maneuver can be initiated in the case of a self-driving vehicle.

An aspect of the invention also relates to a control apparatus which is designed to be connected to a battery and preferably also to a vehicle chassis and is configured to carry out a method according to an aspect of the invention.

An aspect of the invention also relates to a battery sensor which is designed to be connected to a battery and preferably also to a vehicle chassis and is configured to carry out a method according to an aspect of the invention.

The method according to an aspect of the invention can preferably be implemented in suitable components by means of the control apparatus according to an aspect of the invention or the battery sensor according to an aspect of the invention. In this case, it is possible to refer back to all the embodiments and variants of the method described. The control apparatus and the battery sensor can each have, in particular, processor means and storage means, wherein the storage means store program code, the execution of which causes the processor means to behave in a corresponding manner and to carry out a method according to an aspect of the invention.

An aspect of the invention also relates to a non-volatile computer-readable storage medium containing program code, the execution of which causes a processor, a control apparatus or a battery sensor to carry out a method according to an aspect of the invention. In this case, it is possible to refer back to all the embodiments and variants of the method described.

An aspect of the invention also relates to a vehicle electrical system having a battery, a battery sensor connected to the battery, a control apparatus and a generator. The generator is preferably driven by an internal combustion engine.

The battery, the battery sensor and the generator have a common positive line. In particular, they also have a common ground.

In this case, provision is made, in particular, for the control apparatus to be designed according to an aspect of the invention or for the battery sensor to be designed according to an aspect of the invention. It typically suffices if one of these two components is designed according to an aspect of the invention. In this case, it is possible to refer back to all the embodiments and variants described.

### BRIEF DESCRIPTION OF THE DRAWINGS

Further features and advantages will be gathered by a person skilled in the art from the exemplary embodiments described below with reference to the appended drawing, in which:

FIG. 1: shows a vehicle electrical system in a normal state,

FIG. 2: shows a vehicle electrical system in a fault state,

FIG. 3: shows a typical circuit,

FIG. 4: shows a circuit in a fault state,

FIG. 5: shows a basic illustration of a fault state,

FIG. 6: shows an alternative circuit,

FIG. 7: shows yet another alternative circuit.

### DETAILED DESCRIPTION OF THE PREFERRED EMBODIMENTS

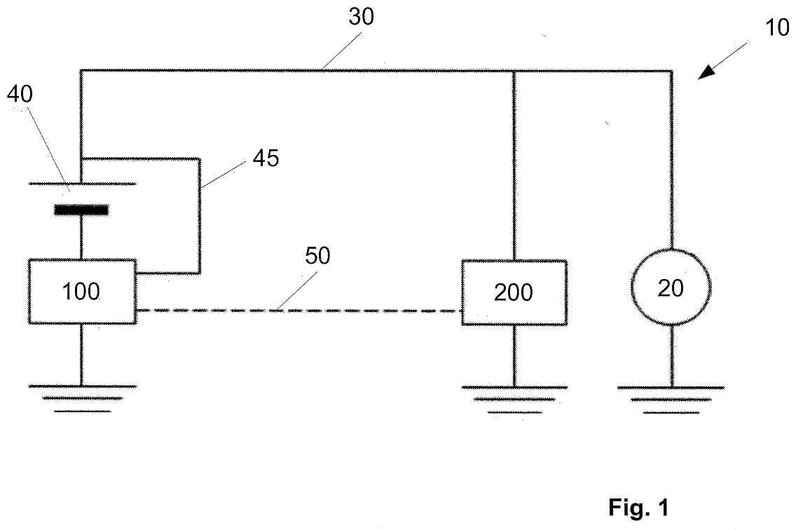

FIG. 1 schematically shows a vehicle electrical system 10 for a motor vehicle. This system has a generator 20, a battery 40, a battery sensor 100 and a control apparatus 200. The battery 40, the control apparatus 200 and the generator 20 are connected to one another via a common positive line 30. The battery sensor 100 is connected between the battery 40 and ground. The generator 20 and the control apparatus 200 are likewise connected to ground. The battery sensor 100 and the control apparatus 200 are communicatively connected to one another via a connection line 50. This is typically a single-wire communication line. It can also be seen that the battery sensor 100 is supplied with the electrical energy needed for its operation from the battery 40 or the generator 20 via a voltage supply line 45.

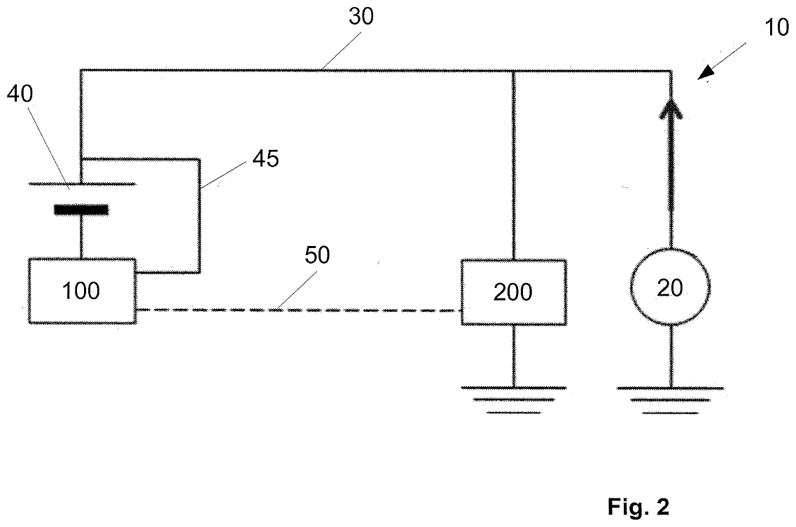

It should be mentioned that FIG. 1 shows a normal state in which the components illustrated are functioning normally and a fault state cannot be detected. In contrast, FIG. 2 shows the vehicle electrical system 10 from FIG. 1 in a fault state. In this case, the connection between the battery sensor 100 and the ground is lost. This may occur, for example, as a result of the cable used for this purpose burning out or breaking.

On the positive side, all components are still attached to the positive line 30. However, the battery sensor 100 and the battery 40 no longer have a common ground with respect to the control apparatus 200 and the generator 20. Therefore, current no longer flows from the vehicle electrical system 10 into the battery 40 and also does not flow from the battery 40 into the vehicle electrical system 10. Since the battery current falls to 0, a typical battery voltage of approximately 11.5 V to 13 V, for example, is established if a typical nominal battery voltage of 12 V is taken as a basis, for example. The generator 20 is still regulated to a charging voltage of typically 13.8 V to 14.8 V and a corresponding current flow is depicted by an arrow in FIG. 2. Since the battery 40 is also omitted as a filter for the AC components of the generator 20, the voltage in the vehicle electrical system 10 is also superposed by a high AC voltage component.

Although the above-described information indicating that the battery current is 0 A and the voltage is between 11.5 V and 13 V can be fundamentally used individually or together as criteria for such a fault state, it is typically not sufficient per se to infer a ground interruption. This is because such measured values can also be set, for example, in the rest state of a vehicle. A ground interruption can be inferred, in particular, in the control apparatus 200 if the communication to the battery sensor 100 is missing and/or if the battery sensor 100 provides a current of virtually or exactly 0 A, to be precise at a stable voltage, in particular, while the control apparatus 200 measures an unstable voltage or a voltage which is considerably too high. These criteria may likewise be used individually or together or else together with other criteria in order to infer a ground interruption or another fault state.

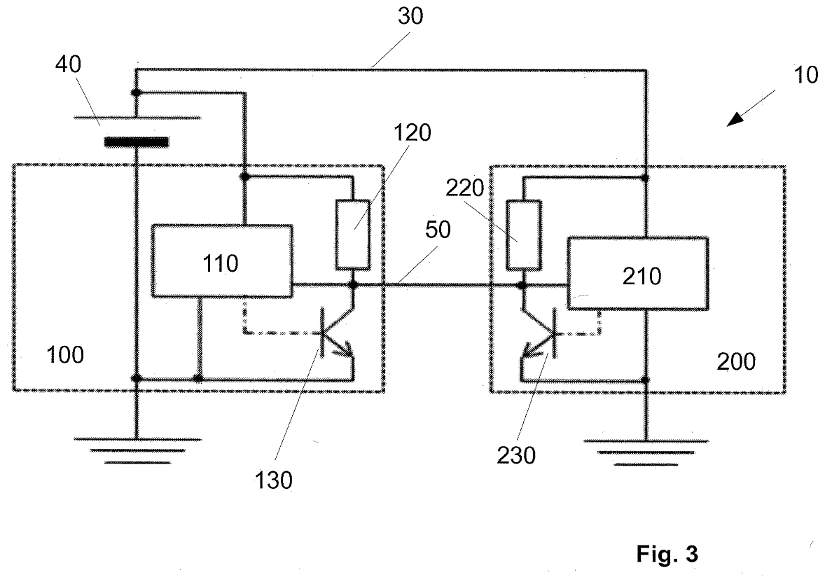

FIG. 3 shows how properties of the typically single-wire connection line 50 can be used to determine the ground interruption. It shows, in particular, the typical circuit of an LIN connection line.

In this case, it can also be seen that the battery sensor 100 has a control unit 110, a resistor 120 and a transistor 130 which are typically connected in such a manner that two digital states can therefore be applied to the connection line 50. The resistor 120 is typically a pull-up resistor. The control apparatus 200 likewise has a control unit 210, a resistor 220 and a transistor 230 which are likewise connected in such a manner that two digital states can be conventionally applied to the connection line 50.

The connection line 50 is normally at the vehicle electrical system voltage. The voltage can be pulled down to virtually 0 V by actuating the transistors 130, 230 in the battery sensor 100 or in the control apparatus 200. In the case of an exemplary switch resistance, that is to say, in particular, a resistance of the respective transistor 130, 230 of 20Ω, and a vehicle electrical system voltage of 12 V, an arithmetic voltage of 235 mV results. The difference between the vehicle electrical system voltage (for example 12 V) and 235 mV is detected by the respective control unit 110, 210 and is interpreted as continuous ones and zeros.

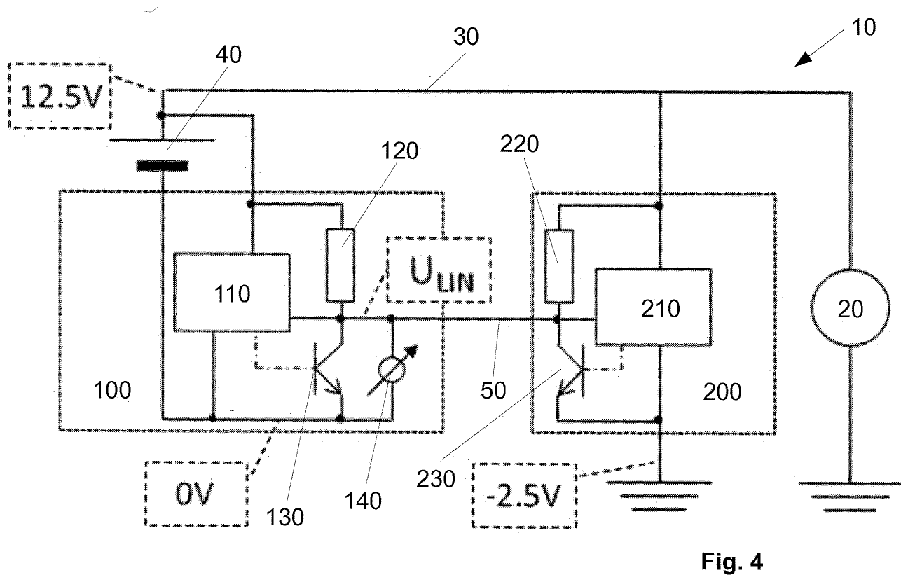

The scenario illustrated in FIG. 4 results in the case of a ground interruption. In this case, a voltmeter 140 is also illustrated in the battery sensor 100 and measures the voltage on the connection line 50. It should be mentioned that this voltmeter is designed, in particular, in such a manner that it cannot only distinguish a logic zero from a logic one but rather can measure a more accurate value of the applied voltage. This is the voltage ULIN depicted.

Further voltage values are also depicted in FIG. 4 and are explained below.

The ground of the battery sensor 100 is at battery minus and is defined as 0 V. As a result of a battery voltage of 12.5 V, for example, the vehicle electrical system 10, that is to say, in particular, the positive line 30, is then also at 12.5 V. If the generator 20 provides a voltage of 15 V, for example, the ground is then at a voltage of −2.5 V.

If the transistor 140 in the battery sensor 100 now had a high impedance, but the transistor 230 in the control apparatus 200 had a low impedance, and if the voltage on the connection line 50 were measured, a value of −2.5 V+15 V×20 mΩ/1020 mΩ=−2.2 V would result with the above example. In comparison with the voltage of approximately +0.3 V normally measured in the battery sensor 100, this could be detected as a considerable drop.

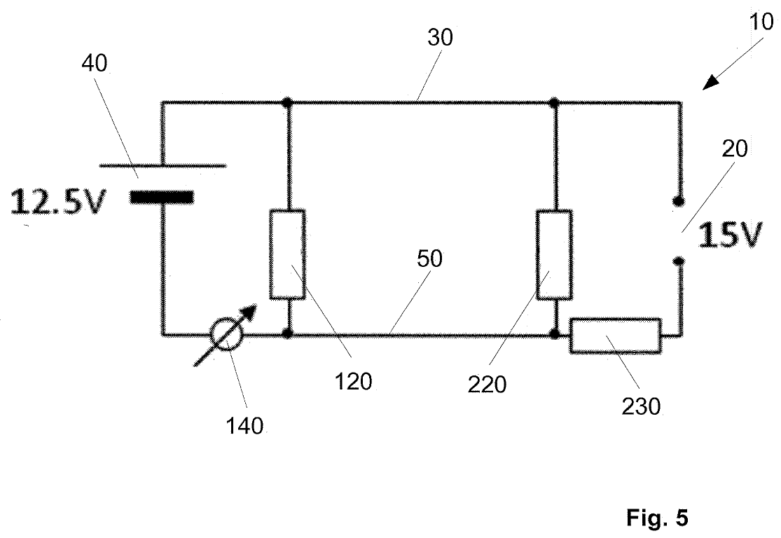

The corresponding circuit diagram is shown in FIG. 5. In this context, it should be mentioned that the resistor 120 of the battery sensor 100 has a resistance value of 30 kΩ, by way of example, the resistor 220 of the control apparatus 200 has a resistance value of 1 kΩ, and the transistor 230 of the control apparatus 200 has an internal resistance of approximately 20Ω. These are exemplary typical values, from which it is also possible to deviate, however.

In comparison with statements according to the prior art, the function whereby the voltage on the connection line 50 or on an LIN bus is explicitly measured and evaluated has been added, as shown. Conventional functions of a battery sensor 100 are the measurement of the battery current, the measurement of the battery voltage, the measurement of the temperature and/or the communication via the connection line 50. Evaluating the voltage of the connection line 50 or of an LIN bus makes it possible to infer the absence of a conductive connection between the battery 40 and the body or ground. This information can be used, in particular, by the control apparatus 200 to deactivate a stop-start function and to consequently avoid breakdowns.

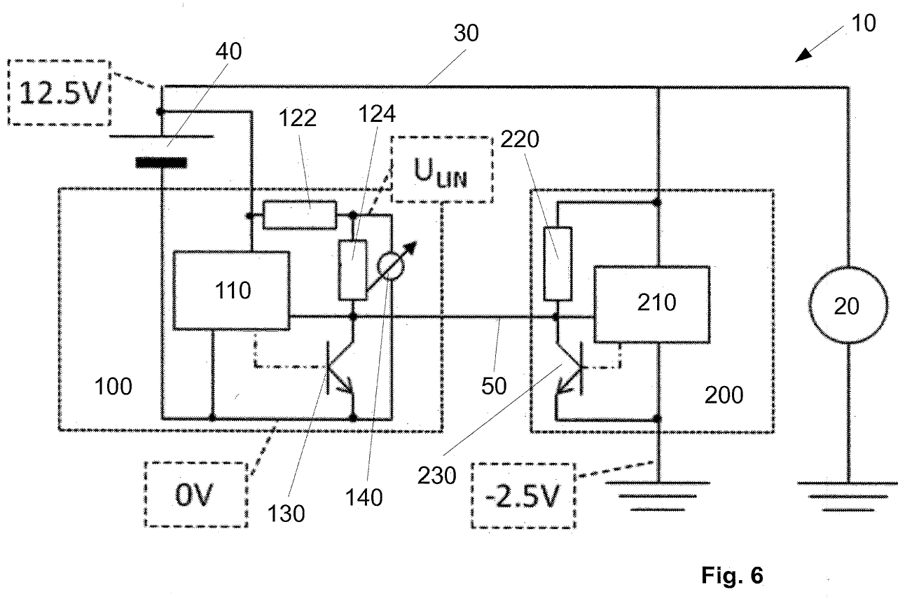

If the control unit 110 or 210 cannot capture any negative voltages, it is also possible to resort to the exemplary embodiment according to FIG. 6. In this case, the resistor 120 of the battery sensor 100, which is used as a pull-up resistor in particular, is replaced with a voltage divider comprising a first resistor 122 and a second resistor 124 which together form a pull-up resistor. In this example, a measurement voltage ULIN of 12.5 V-28 kΩ/30 kΩ×(12.5 V+2.5 V)=0 V would result instead of normally 2.1 V.

It would additionally be possible to evaluate the AC component or AC voltage component of the measurement voltage ULIN, which can assume very large values if a battery 40 is missing. An additional criterion would be a measurement current of virtually 0 A. A comparison of the measurement voltage ULIN with the battery voltage normally measured in the battery sensor 100 can also be used. It should be understood that all criteria disclosed herein can fundamentally be used both individually and in any desired combination and with any desired logic operations.

The voltmeter 140 of the battery sensor 100 can also be used to measure the battery voltage of the battery 40, for example. This can be carried out by means of multiplexing, for example. A. measuring channel for measuring the battery current could also be used to determine ULIN.

It is useful, in particular, to evaluate minimum voltages, that is to say if the control apparatus 200 pulls the voltage of the connection line 50 to ground. This can correspond to a logic zero, for example. An evaluation is typically carried out only when the control unit 110 of the battery sensor 100 has not switched the transistor 130 to low impedance.

A voltage of the connection line 50 can be temporally resolved to 0.1 ms to 2 ms, for example, using exemplary typical hardware of a battery sensor 100. However, the conventional transmission rate may be 19.2 kB, for example, which corresponds to 0.052 ms per bit. This means that the respective other unit, that is to say, in particular, the control apparatus 200 in the present example, advantageously transmits 2 to 4 bits (a frame comprises 64 bits) at a low voltage, for example, in order to be able to directly measure the minimum voltage.

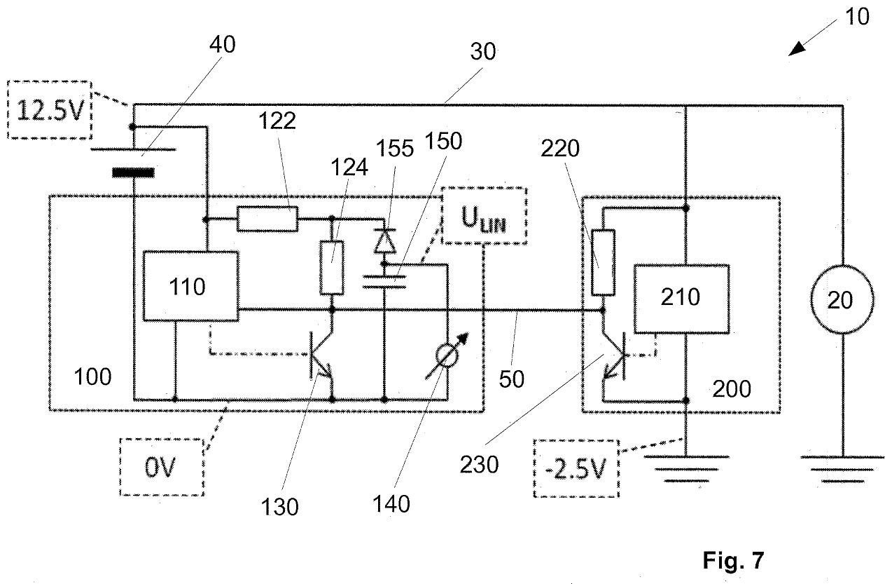

As an alternative to directly measuring the voltage of the connection line 50 by means of an analog/digital converter, it is also possible to provide a hardware solution which buffers the minimum voltage in a capacitor, which can be achieved, for example, by means of a sample-and-hold circuit. Such an embodiment is illustrated, for example, in FIG. 7. For this purpose, a capacitor 150 and a diode 155 connected to the latter are arranged in the battery sensor 100.

The described functionality could fundamentally also be implemented in a battery sensor 100 having current measurement on the positive side. The following are advantageous, in particular:
a conductive electrical connection to the vehicle electrical system 10,
a conductive electrical connection to the negative pole of the battery 40,
a conductive electrical connection (for example LIN) which at least occasionally has a voltage close to the body.

A solution in the control apparatus 200 instead of an implementation inside the battery sensor 100 would also be conceivable. For this purpose, the battery sensor 100 should capture, for example, information relating to
the absolute battery voltage,
the AC component or AC voltage component of the battery voltage, and
the information indicating that the battery current is approximately 0 A and should advantageously transmit it to the control apparatus 200.

A ground drop of the battery 40 can likewise be inferred by measuring the voltage in the control apparatus 200 and comparing it with the values from the battery sensor 100.

The advantage of an embodiment in the battery sensor 100 is that the problem of the risk of the communication on the connection line 50 also no longer reliably functioning in the event of a loss of the ground connection is avoided. If the communication no longer reliably functions, it is also typically no longer possible to transmit the detected fault.

A further power source, in particular the generator 20, for supplying the vehicle electrical system is advantageously present for the purpose of detecting a ground interruption of a battery 40. The generator 20 is typically driven by an internal combustion engine.

It should be mentioned that it is also possible to detect the breakage of a positive battery cable, specifically using a corresponding configuration, in particular. In this case, the maximum voltage rather than the minimum voltage is advantageously analyzed.

Mentioned steps of the method according to an aspect of the invention can be executed in the indicated order. However, they can also be executed in a different order. In one of its embodiments, for example with a specific combination of steps, the method according to an aspect of the invention can be executed in such a way that no further steps are executed.

However, in principle, further steps can also be executed, even steps of a kind which have not been mentioned.

The claims that are part of the application do not represent any dispensing with the attainment of further protection.

If it turns out in the course of the proceedings that a feature or a group of features is not absolutely necessary, then the applicant aspires right now to a wording for at least one independent claim that no longer has the feature or the group of features. This may be, by way of example, a subcombination of a claim present on the filing date or may be a subcombination of a claim present on the filing date that is limited by further features.

Claims or combinations of features of this kind requiring rewording can be understood to be covered by the disclosure of this application as well.

It should further be pointed out that configurations, features and variants of aspects of the invention that are described in the various embodiments or exemplary embodiments and/or shown in the figures are combinable with one another in any way. Single or multiple features can be interchanged with one another in any way. Combinations of features arising therefrom can be understood to be covered by the disclosure of this application as well.

Back-references in dependent claims are not intended to be understood as dispensing with the attainment of independent substantive protection for the features of the back-referenced subclaims. These features can also be combined with other features in any way.

Features that are disclosed only in the description or features that are disclosed in the description or in a claim only in conjunction with other features may fundamentally be of independent significance essential to aspects of the invention. They can therefore also be individually included in claims for the purpose of distinction from the prior art.

1. A method for detecting a fault state in a vehicle electrical system by a battery sensor and a control apparatus,
wherein the battery sensor and the control apparatus are connected to one another via at least one connection line for the purpose of communication,
wherein the method comprises:
measuring a line voltage on the connection line,
determining whether the line voltage is within at least a predefined normal range, and
determining the fault state if the line voltage is outside the normal range.

2. The method as claimed in claim 1,
wherein the fault state corresponds to a loss of a connection between the battery sensor and ground.

3. The method as claimed in claim 1,
wherein the method is carried out in the control apparatus;
or
wherein the method is carried out in the battery sensor.

4. The method as claimed in claim 1,
wherein the normal range is in the positive voltage range.

5. The method as claimed in claim 1,
wherein the fault state is determined only when the line voltage is in a fault range, and
wherein the fault range is in the negative voltage range.

6. The method as claimed in claim 1,
wherein the line voltage is measured relative to a reference potential which is preferably generated by a pull-up resistor in the form of a voltage divider.

7. The method as claimed in claim 1,
wherein the fault state is also determined on the basis of one or more of the following criteria:
an AC voltage component of a battery voltage measured by the battery sensor,
a current measured by the battery sensor which is below a threshold value in terms of absolute value,
a comparison of the battery voltage measured by the battery sensor with a normal value or with a further normal range.

8. The method as claimed in claim 1,
wherein the fault state is determined even if the communication between the battery sensor and the control apparatus is terminated.

9. The method as claimed in claim 1,
wherein the line voltage is measured while the connection line is connected to ground opposite the voltage-measuring unit and is not connected to ground at the voltage-measuring unit.

10. The method as claimed in claim 1,
wherein the line voltage is measured with a low level over a number or a plurality of data transmission cycles.

11. The method as claimed in claim 1,
wherein the fault state corresponds to a loss of a connection between the battery sensor and the battery, and
wherein the line voltage is measured with a high level over a number or a plurality of data transmission cycles.

12. The method as claimed in claim 1,
wherein the disconnection of an internal combustion engine is deactivated in response to the determination of the fault state.

13. A control apparatus which is designed to be connected to a battery and also to a vehicle chassis and is configured to carry out a method as claimed in claim 1.

14. A battery sensor which is designed to be connected to a battery and also to a vehicle chassis and is configured to carry out a method as claimed in claim 1.

15. A vehicle electrical system comprising:
a battery,
a battery sensor which is connected to the battery,
a control apparatus, and
a generator which is driven by an internal combustion engine,
wherein the battery, the battery sensor and the generator have a common positive line and a common ground, and
wherein the control apparatus is designed as claimed in claim 13.

16. A vehicle electrical system comprising:
a battery,
a battery sensor which is connected to the battery,
a control apparatus, and
a generator which is driven by an internal combustion engine,
wherein the battery, the battery sensor and the generator have a common positive line and a common ground, and
wherein the battery sensor is designed as claimed in claim 14.

17. The method as claimed in claim 7, wherein the measured current is a current of the battery.

18. The method as claimed in claim 2,
wherein the method is carried out in the control apparatus;
or
wherein the method is carried out in the battery sensor.
